(19) United States
(12) Patent Application Publication
(10) Pub. No.: US 2026/0363150 A1
(43) Pub. Date: Nov. 12, 2026

(54) SEMICONDUCTOR STRUCTURES INCLUDING WIRE-BOND PADS AND FLIP-CHIP BUMPS AND METHOD OF MAKING THE SAME

(71) Applicant: Taiwan Semiconductor Manufacturing Company Limited, Hsinchu (TW)

(72) Inventors: Yun-Chi Wu, Tainan City (TW); Cheng-Bo Shu, Tainan City (TW); Po-Wei Liu, Tainan City (TW)

(21) Appl. No.: 19/748,268

(22) Filed: Jul. 21, 2026

Related U.S. Application Data
(62) Division of application No. 18/526,331, filed on Dec. 1, 2023.

(51) Int. Cl. H10W 90/00; H10W 70/685; H10W 72/20; H10W 72/90; H10W 74/10

(52) U.S. Cl. CPC H10W 90/701; H10W 70/685; H10W 90/00; H10W 72/244; H10W 72/252; H10W 72/9415; H10W 72/952; H10W 74/142

(57) ABSTRACT

A semiconductor structure may include a wire-bond pad including a first electrically conducting surface, a flip-chip bump including a second electrically conducting surface, a polymer layer formed over a surface of the semiconductor structure, wherein the first electrically conducting surface of the wire-bond pad is located under a first opening in the polymer layer, and wherein the flip-chip bump extends through a second opening in the polymer layer.

### CROSS-REFERENCE TO RELATED APPLICATIONS

This application is a divisional patent application of U.S. Application No. 18/526,331, entitled “Semiconductor Structures Including Wire-Bond Pads and Flip-Chip Bumps and Method of Making the Same” filed Dec. 1, 2023, which is hereby incorporated by reference in its entirety for all purposes.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers over a semiconductor substrate, and patterning the various material layers using lithography and etching to form circuit components and elements thereon. Dozens, hundreds, or thousands of integrated circuits are typically manufactured on a single semiconductor wafer. Individual dies on the wafer may be singulated by sawing between the integrated circuits along scribe lines. The individual dies are typically packaged separately, in multi-chip modules, or in other types of packaging, for example.

Both flip-chip and wire bonding are techniques used in semiconductor packaging to establish electrical connections between chips and other components, such as substrates, printed circuit boards, or other chips. While they have different characteristics and advantages, there are situations where both flip-chip and wire bonding might be used within the same semiconductor package, depending on the specific requirements of the application. Further, in various applications, semiconductor dies having both wire bond pads and flip-chip bumps may provide flexibility in how such dies are integrated into different packaging configurations.

### BRIEF DESCRIPTION OF THE DRAWINGS

Aspects of this disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a vertical cross-sectional view of a first exemplary structure after formation of complementary metal-oxide-semiconductor (CMOS) transistors, first metal interconnect structures formed in lower-level dielectric material layers, and an isolation dielectric layer, according to various embodiments.

FIG. 2A is a three-dimensional perspective view of a wafer-level semiconductor structure including a plurality of semiconductor structures formed thereon, according to various embodiments.

FIG. 2B is a top view of one of the plurality of semiconductor structures of FIG. 2A, according to various embodiments.

FIG. 2C is a top expanded view of a portion of the semiconductor structure of FIG. 2B, according to various embodiments.

FIG. 2D is a vertical cross-sectional view of the portion of the semiconductor structure of FIG. 2C, according to various embodiments.

FIG. 3A is a vertical cross-sectional view of an intermediate structure that may be used in the formation of a semiconductor structure, according to various embodiments.

FIG. 3B is a vertical cross-sectional view of a further intermediate structure that may be used in the formation of a semiconductor structure, according to various embodiments.

FIG. 3C is a vertical cross-sectional view of a further intermediate structure that may be used in the formation of a semiconductor structure, according to various embodiments.

FIG. 3D is a vertical cross-sectional view of a further intermediate structure that may be used in the formation of a semiconductor structure, according to various embodiments.

FIG. 3E is a vertical cross-sectional view of a further intermediate structure that may be used in the formation of a semiconductor structure, according to various embodiments.

FIG. 3F is a vertical cross-sectional view of a further intermediate structure that may be used in the formation of a semiconductor structure, according to various embodiments.

FIG. 3G is a vertical cross-sectional view of a further intermediate structure that may be used in the formation of a semiconductor structure, according to various embodiments.

FIG. 3H is a vertical cross-sectional view of a further intermediate structure that may be used in the formation of a semiconductor structure, according to various embodiments.

FIG. 3I is a vertical cross-sectional view of a further intermediate structure that may be used in the formation of a semiconductor structure, according to various embodiments.

FIG. 3J is a vertical cross-sectional view of a further intermediate structure that may be used in the formation of a semiconductor structure, according to various embodiments.

FIG. 3K is a vertical cross-sectional view of a further intermediate structure that may be used in the formation of a semiconductor structure, according to various embodiments.

FIG. 3L is a vertical cross-sectional view of a further intermediate structure that may be used in the formation of a semiconductor structure, according to various embodiments.

FIG. 3M is a vertical cross-sectional view of a further intermediate structure that may be used in the formation of a semiconductor structure, according to various embodiments.

FIG. 3N is a vertical cross-sectional view of a further intermediate structure that may be used in the formation of a semiconductor structure, according to various embodiments.

FIG. 4 is a flowchart illustrating operations of a method of forming a semiconductor structure, according to various embodiments.

### DETAILED DESCRIPTION

The following disclosure provides many different embodiments, or examples, for implementing different features of the provided subject matter. Specific examples of components and arrangements are described below to simplify this disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, this disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Unless explicitly stated otherwise, each element having the same reference numeral is presumed to have the same material composition and to have a thickness within a same thickness range.

Various embodiments disclosed herein may be advantageous by providing wafer-level semiconductor structures having wire-bond pads and flip-chip bumps that have electrically conductive surfaces. In this regard, a polymer layer deposited over the wire-bond pads during formation of the flip-chip bumps may be etched subsequent to the formation of the flip-chip bumps to expose a conductive surface of the wire-bond pads. As such, wafer-level testing may be carried out on both wire-bond pads and flip-chip bumps before singulating wafer-level semiconductor structures into semiconductor dies. Such testing may provide advantages by allowing screening for potential damage that may result due to multiple CMOS fabrication processes and high temperatures used in the formation of the polymer layer. Package-level testing may be performed after the semiconductor dies have been singulated and assembled into semiconductor packages. Semiconductor dies having both wire-bond pads and flip-chip bumps may be used in situations where both flip-chip and wire bonding may be used within the same semiconductor package and may provide flexibility in how such semiconductor dies may be integrated into different packaging configurations.

An embodiment wafer-level semiconductor structure may include a semiconductor substrate having a plurality of semiconductor structures formed thereon. Each wafer-level semiconductor structure may include a plurality of bonding structures electrically connected to the semiconductor structures. The plurality of bonding structures may be formed on a dielectric substrate. Each of the plurality of bonding structures may include a wire-bond pad having a first electrically conducting surface and a flip-chip bump including a second electrically conducting surface. The semiconductor structures may include a flip-chip bond pad and a first passivation layer formed over a surface of the semiconductor structure including a plurality of electrical contact structures. The wire-bond pad may extend through the first passivation layer and may be electrically connected to a first one of the electrical contact structures and the flip-chip bump may be connected to the flip-chip bond pad, which extends through the first passivation layer and is electrically connected to a second one of the electrical contact structures.

According to a further embodiment, a semiconductor structure may include a wire-bond pad including a first electrically conducting surface, a flip-chip bump including a second electrically conducting surface, a first passivation layer, a second passivation layer, and a polymer layer formed over the second passivation layer. The first electrically conducting surface of the wire-bond pad may be located under first openings in the first passivation layer, second openings in the second passivation layer, and third openings in the polymer layer and the flip-chip bump may extend through first openings in the first passivation layer, second openings in the second passivation layer, and third openings in the polymer layer.

According to a further embodiment, a method of forming a semiconductor structure may include forming a plurality of semiconductor circuits on a semiconductor substrate, such that the plurality of semiconductor circuits includes a plurality of electrical contact structures formed at a surface of a dielectric substrate. The method may further include forming, on each of the plurality of electrical contact structures, a wire-bond pad and a flip-chip bond pad. The method may further include forming a polymer layer over the wire-bond pad and the flip-chip bond pad and etching or lithographic patterning the polymer layer to expose a first electrically conducting surface of the wire-bond pad and an intermediate electrically conducting surface of the flip-chip bond pad. The method may further include forming a patterned mask that masks the first electrically conducting surface of the wire-bond pad and exposes the intermediate electrically conducting surface of the flip-chip bond pad. The method may further include depositing a first electrically conducting material over the patterned mask to thereby form a flip-chip bump over the intermediate electrically conducting surface of the flip-chip bond pad such that the flip-chip bump comprising a second electrically conducting surface. The method may further include removing the patterned mask.

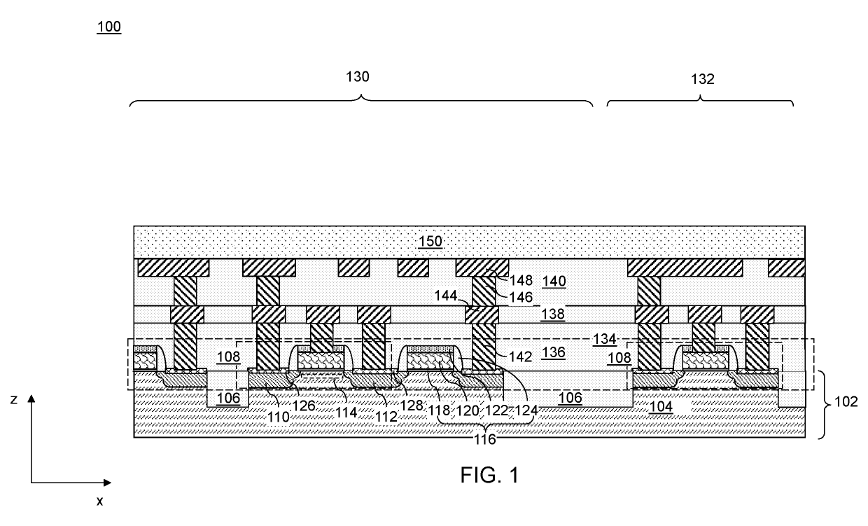

FIG. 1 illustrates a first exemplary semiconductor structure 100, according to various embodiments. The first exemplary structure 100 includes a semiconductor substrate 102, which may be a semiconductor substrate such as a commercially available silicon substrate. The semiconductor substrate 102 may include a semiconductor material layer 104 at least at an upper portion thereof. The semiconductor material layer 104 may be a surface portion of a bulk semiconductor substrate, or may be a top semiconductor layer of a semiconductor-on-insulator (SOI) substrate. In one embodiment, the semiconductor material layer 104 may include a single crystalline semiconductor material such as single crystalline silicon. In one embodiment, the semiconductor substrate 102 may include a single crystalline silicon substrate including a single crystalline silicon material.

Shallow trench isolation structures 106 including a dielectric material such as silicon oxide may be formed in an upper portion of the semiconductor material layer 104. Suitable doped semiconductor wells, such as p-type wells and n-type wells, may be formed within each area that is laterally enclosed by a portion of the shallow trench isolation structures 106. Field effect transistors 108 may be formed over the top surface of the semiconductor material layer 104. For example, each field effect transistor 108 may include a source electrode 110, a drain electrode 112, a semiconductor channel 114 that includes a surface portion of the semiconductor substrate 102 extending between the source electrode 110 and the drain electrode 112, and a gate structure 116. The semiconductor channel 114 may include a single crystalline semiconductor material. Each gate structure 116 may include a gate dielectric layer 118, a gate electrode 120, a gate cap dielectric 122, and a dielectric gate spacer 124. A source-side metal-semiconductor alloy region 126 may be formed on each source electrode 110, and a drain-side metal-semiconductor alloy region 128 may be formed on each drain electrode 112.

The first exemplary structure may include a memory array region 130 in which an array of memory cells may be subsequently formed. The first exemplary structure may further include a peripheral region 132 in which metal wiring for an array of memory devices (e.g., ferroelectric memory devices or other devices to be formed subsequently) is provided. Generally, the field effect transistors 108 in the CMOS circuitry 134 may be electrically connected to an electrode of a respective memory cell (or other device) by a respective set of metal interconnect structures.

Devices (such as field effect transistors 108) in the peripheral region 132 may provide functions that operate the array of memory cells to be subsequently formed. Specifically, devices in the peripheral region may be configured to control the programming operation, the erase operation, and the sensing (read) operation of the array of memory cells. For example, the devices in the peripheral region may include a sensing circuitry and/or a programming circuitry. The devices formed on the top surface of the semiconductor material layer 104 may include complementary metal-oxide-semiconductor (CMOS) transistors and optionally additional semiconductor devices (such as resistors, diodes, capacitors, etc.), and are collectively referred to as CMOS circuitry 134.

One or more of the field effect transistors 108 in the CMOS circuitry 134 may include a semiconductor channel 114 that contains a portion of the semiconductor material layer 104 in the semiconductor substrate 102. In embodiments in which the semiconductor material layer 104 may include a single crystalline semiconductor material such as single crystalline silicon, the semiconductor channel 114 of each field effect transistor 108 in the CMOS circuitry 134 may include a single crystalline semiconductor channel such as a single crystalline silicon channel. In one embodiment, a plurality of field effect transistors 108 in the CMOS circuitry 134 may include a respective node that is subsequently electrically connected to a node of a respective ferroelectric memory cell to be subsequently formed. For example, a plurality of field effect transistors 108 in the CMOS circuitry 134 may include a respective source electrode 110 or a respective drain electrode 112 that is subsequently electrically connected to a node of a respective memory cell (e.g., ferroelectric memory cell or another device) to be subsequently formed.

In one embodiment, the CMOS circuitry 134 may include a programming control circuit configured to control gate voltages of a set of field effect transistors 108 that may be used for programming a respective memory cell (e.g., a ferroelectric memory cell) and to control gate voltages of transistors (e.g., TFTs) to be subsequently formed. In this embodiment, the programming control circuit may be configured to provide a first programming pulse that programs a respective ferroelectric dielectric material layer in a selected ferroelectric memory cell into a first polarization state in which electrical polarization in the ferroelectric dielectric material layer points toward a first electrode of the selected ferroelectric memory cell, and to provide a second programming pulse that programs the ferroelectric dielectric material layer in the selected ferroelectric memory cell into a second polarization state in which the electrical polarization in the ferroelectric dielectric material layer points toward a second electrode of the selected ferroelectric memory cell.

In one embodiment, the semiconductor substrate 102 may include a single crystalline silicon substrate, and the field effect transistors 108 may include a respective portion of the single crystalline silicon substrate as a semiconducting channel. As used herein, a “semiconducting” element refers to an element having electrical conductivity in the range from 1.0 x 10⁻⁶ S/cm to 1.0 x 10⁵ S/cm. As used herein, a “semiconductor material” refers to a material having electrical conductivity in the range from 1.0 x 10⁻⁶ S/cm to 1.0 x 10⁵ S/cm in the absence of electrical dopants therein, and is capable of producing a doped material having electrical conductivity in a range from 1.0 S/cm to 1.0 x 10⁵ S/cm upon suitable doping with an electrical dopant.

According to an aspect of the disclosure, the field effect transistors 108 may be subsequently electrically connected to drain electrodes and gate electrodes of access transistors including semiconducting metal oxide plates to be formed above the field effect transistors 108. In one embodiment, a subset of the field effect transistors 108 may be subsequently electrically connected to at least one of the drain electrodes and the gate electrodes. For example, the field effect transistors 108 may include first word line drivers configured to apply a first gate voltage to first word lines through a first subset of lower-level metal interconnect structures to be subsequently formed, and second word line drivers configured to apply a second gate voltage to second word lines through a second subset of the lower-level metal interconnect structures. Further, the field effect transistors 108 may include bit line drivers configured to apply a bit line bias voltage to bit lines to be subsequently formed, and sense amplifiers configured to detect electrical current that flows through the bit lines during a read operation.

Various metal interconnect structures formed within dielectric material layers may be subsequently formed over the semiconductor substrate 102 and the semiconductor devices thereupon (such as field effect transistors 108). In an illustrative example, the dielectric material layers may include, for example, a first dielectric material layer 136 that may be a layer that surrounds the contact structure connected to the source and drains (sometimes referred to as a contact-level dielectric material layer 136), a first interconnect-level dielectric material layer 138, and a second interconnect-level dielectric material layer 140. The metal interconnect structures may include device contact via structures 142 formed in the first dielectric material layer 136 and contacting a respective component of the CMOS circuitry 134, first metal line structures 144 formed in the first interconnect-level dielectric material layer 138, first metal via structures 146 formed in a lower portion of the second interconnect-level dielectric material layer 140, and second metal line structures 148 formed in an upper portion of the second interconnect-level dielectric material layer 140.

Each of the dielectric material layers (136, 138, 140) may include a dielectric material such as undoped silicate glass, a doped silicate glass, organosilicate glass, amorphous fluorinated carbon, porous variants thereof, or combinations thereof. Each of the metal interconnect structures (142, 144, 146, 148) may include at least one conductive material, which may be a combination of a metallic liner (such as a metallic nitride or a metallic carbide) and a metallic fill material. Each metallic liner may include TiN, TaN, WN, TiC, TaC, and WC, and each metallic fill material portion may include W, Cu, Al, Co, Ru, Mo, Ta, Ti, alloys thereof, and/or combinations thereof. Other suitable metallic liner and metallic fill materials within the contemplated scope of disclosure may also be used. In one embodiment, the first metal via structures 146 and the second metal line structures 148 may be formed as integrated line and via structures by a dual damascene process. The dielectric material layers (136, 138, 140) are herein referred to as lower-level dielectric material layers. The metal interconnect structures (142, 144, 146, 148) formed within in the lower-level dielectric material layers are herein referred to as lower-level metal interconnect structures.

While the disclosure is described using an embodiment in which an array of memory cells may be formed over the second line-and-via-level dielectric material layer 140, embodiments are expressly contemplated herein in which the array of memory cells may be formed at a different metal interconnect level.

An array of transistors (e.g., thin film transistors) and an array of memory cells (e.g., ferroelectric memory cells or other types of memory cells) may be subsequently deposited over the dielectric material layers (136, 138, 140) that have formed therein the metal interconnect structures (142, 144, 146, 148). The set of all dielectric material layer that are formed prior to formation of an array of thin film transistors or an array of ferroelectric memory cells is collectively referred to as lower-level dielectric material layers (136, 138, 140). The set of all metal interconnect structures that is formed within the lower-level dielectric material layers (136, 138, 140) is herein referred to as first metal interconnect structures (142, 144, 146, 148). Generally, first metal interconnect structures (142, 144, 146, 148) formed within at least one lower-level dielectric material layer (136, 138, 140) may be formed over the semiconductor material layer 104 that is located in the semiconductor substrate 102.

According to various embodiments, a planar dielectric material layer having a uniform thickness may be formed over the lower-level dielectric material layers (136, 138, 140). The planar dielectric material layer is herein referred to as an insulating matrix layer 150. The insulating matrix layer 150 may include a dielectric material such as undoped silicate glass, a doped silicate glass, organosilicate glass, or a porous dielectric material, and may be deposited by chemical vapor deposition. The thickness of the insulating matrix layer 150 may be in a range from 20 nm to 300 nm, although lesser and greater thicknesses may also be used.

Generally, interconnect-level dielectric layers (such as the lower-level dielectric material layer (136, 138, 140)) containing therein the metal interconnect structures (such as the first metal interconnect structures (142, 144, 146, 148)) may be formed over semiconductor devices. The insulating matrix layer 150 may be formed over the interconnect-level dielectric layers. Other passive devices may be formed in back-end-of-line (BEOL) processes. For example various capacitor structures may be utilized with other BEOL devices.

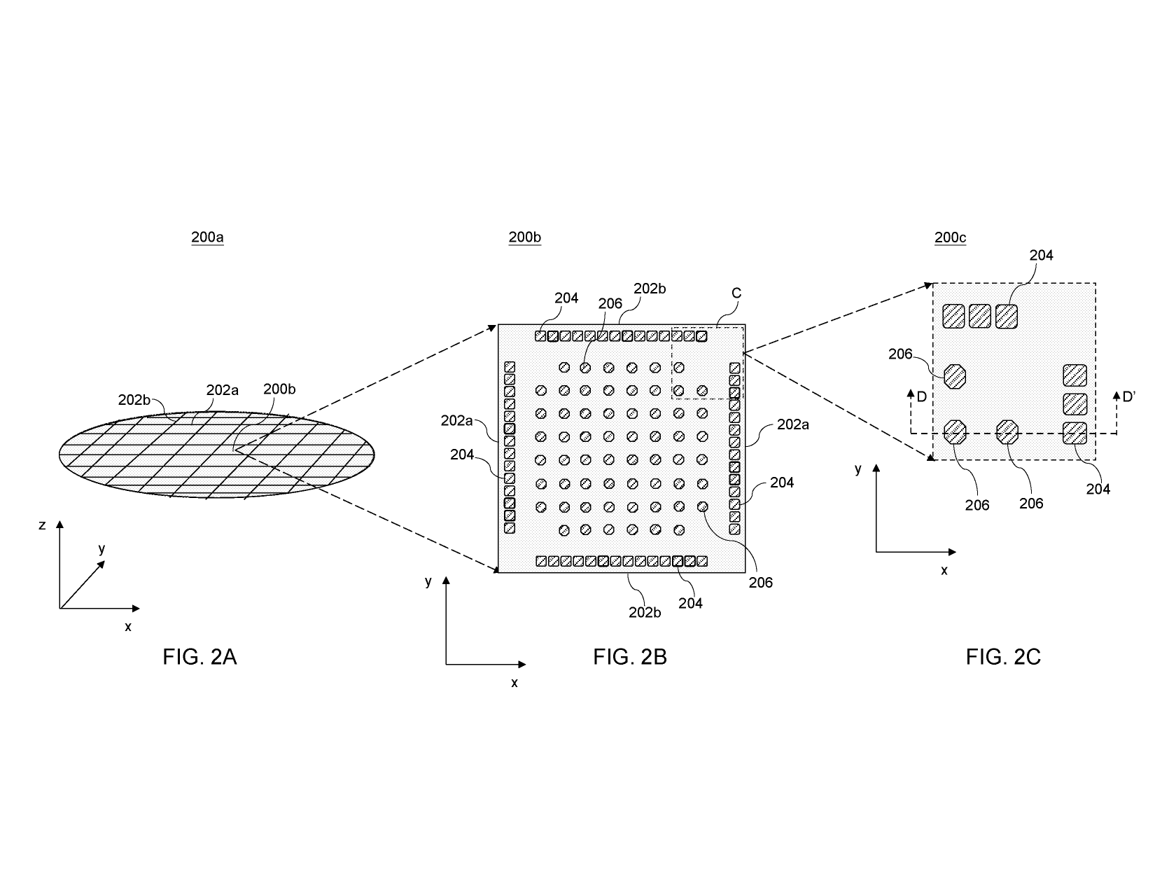

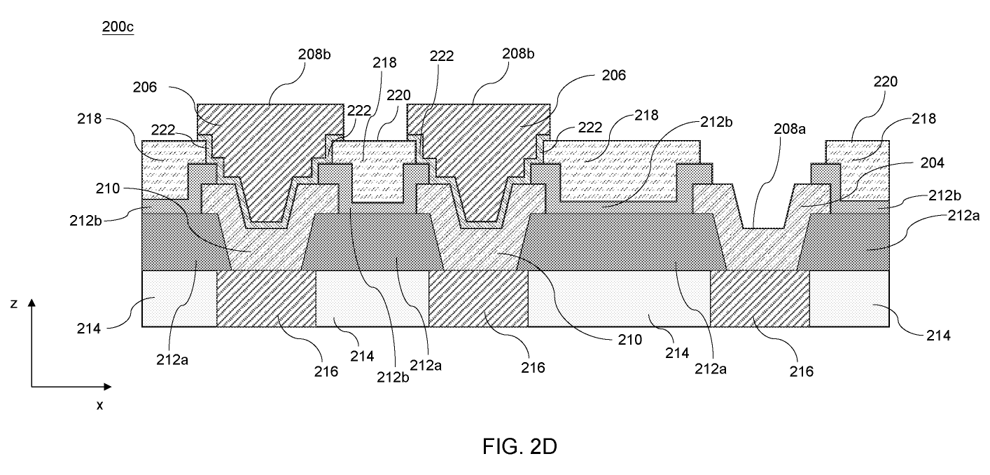

FIG. 2A is a three-dimensional perspective view of a semiconductor wafer-level structure 200a including a plurality of semiconductor structures 200b formed thereon, FIG. 2B is a top view of one of the plurality of semiconductor structures 200b of FIG. 2A, and FIG. 2C is a top expanded view of a portion 200c of the semiconductor structure 200b of FIG. 2B, according to various embodiments. The portion 200c of the semiconductor structure 200b of FIG. 2B shown in FIG. 2C is indicated by the dashed region labeled “C” in FIG. 2B. A vertical cross-sectional view, described in greater detail with reference to FIG. 2D, below, is indicated by the cross section D – D’ in FIG. 2C. The plurality of semiconductor structures 200b may be formed on the semiconductor wafer-level structure 200a using processing operations similar to those described above with reference to FIG. 1.

As shown in FIG. 2A, the semiconductor wafer-level structure 200a may include a first plurality of scribe lines 202a aligned with a first direction (e.g., the x-direction) and a second plurality of scribe lines 202b aligned with a second direction (e.g., the y-direction). The semiconductor wafer-level structure 200a may be singulated along the scribe lines (202a, 202b) in a subsequent processing operation to generate a plurality of semiconductor dies, each containing a respective one of the plurality of semiconductor structures 200b. As such, upon singulating the semiconductor wafer-level structure 200a, each resulting semiconductor die may have a top view similar to that of the semiconductor structure 200b shown in FIG. 2B. As shown in FIGS. 2B and 2C, each of the plurality of semiconductor structures 200b may include a plurality of wire-bond pads 204 and a plurality of flip-chip bumps 206, as described in greater detail with reference to FIG. 2D, below.

FIG. 2D is a vertical cross-sectional view of the portion 200c of the semiconductor structure 200b of FIG. 2C, according to various embodiments. As shown, the portion 200c of the semiconductor structure 200b may include a wire-bond pad 204 and flip-chip bumps 206. The wire-bond pad 204 may have a first electrically conducting surface 208a and the flip-chip bumps 206 may each have a second electrically conducting surface 208b. Each flip-chip bump 206 may be formed over a respective flip-chip bond pad 210, and each of the wire-bond pad 204 and the flip-chip bond pads 210 may be formed within a first passivation layer 212a.

The first passivation layer 212a may be formed over a dielectric substrate 214 that may have formed therein a plurality of electrical contact structures 216 and each of the wire-bond pad 204 and the flip-chip bond pads 210 may be electrically connected to respective ones of the electrical contact structures 216. In this regard, the wire-bond pad 204 may extend through the first passivation layer 212a and may be electrically connected to a first one of the plurality of electrical contact structures 216. Similarly, each flip-chip bump 206 may be connected to a respective flip-chip bond pad 210, which may extend through the first passivation layer 212a, and may be electrically connected to a respective one of the plurality of electrical contact structures 216.

As described above, the dielectric substrate 214 may be a dielectric layer (e.g., an inter-layer dielectric or insulating matrix layer 150 from FIG. 1) that may have formed therein the one or more electrical contact structures 216. The one or more electrical contact structures 216 may be electrically connected to various other interconnect structures (e.g., first metal interconnect structures (142, 144, 146, 148) in FIG. 1) formed below the dielectric substrate 214. Each of the one or more electrical contact structures 216 may include at least one conductive material, which may be a combination of a metallic liner layer (such as a metallic nitride or a metallic carbide) and a metallic fill material. Each metallic liner layer may include TiN, TaN, WN, TiC, TaC, and WC, and each metallic fill material portion may include W, Cu, Al, Co, Ru, Mo, Ta, Ti, alloys thereof, and/or combinations thereof. Other suitable materials within the contemplated scope of disclosure may also be used.

The dielectric substrate 214 may include, for example, undoped silicate glass, a doped silicate glass (e.g., deposited by decomposition of tetraethylorthosilicate (TEOS)), organosilicate glass, silicon oxynitride, or silicon carbide nitride. Other dielectric materials are within the contemplated scope of disclosure. The dielectric material of the dielectric substrate 214 may be deposited by a conformal deposition process (such as a chemical vapor deposition process) or a self-planarizing deposition process (such as spin coating). The thickness of the dielectric substrate 214 may each be in a range from approximately 15 nm to approximately 60 nm, such as from approximately 20 nm to approximately 40 nm, although smaller and larger thicknesses may also be used.

Formation of the one or more electrical contact structures 216 may be completed by depositing a mask layer (not shown) over the dielectric substrate 214 and performing various photolithographic steps to etch a via in the dielectric substrate 214. Deposition of the at least one conductive material, which may be a combination of a metallic liner layer (such as a metallic nitride or a metallic carbide) and a metallic fill material may be performed by any of a variety of deposition techniques such as physical vapor deposition (PVD), chemical vapor deposition (CVD)) or a self-planarizing deposition process (such as spin coating). Other conformal deposition processes may include plasma enhanced chemical vapor deposition (PECVD), atomic layer deposition (ALD), physical vapor deposition (PVD), a high density plasma CVD (HDPCVD) process, a metalorganic CVD (MOCVD) process, a sputtering process, laser ablation, etc.

According to various embodiments, each of the semiconductor structures 200b (as exemplified by the portion 200c of the semiconductor structure 200b of FIG. 2C) may include one or more additional passivation layers formed over the first passivation layer 212a. For example, as shown in FIG. 2D, a second passivation layer 212b may be formed over the first passivation layer 212a. Further, according to various embodiments, a polymer layer 218 may be formed over the second passivation layer 212b. In various embodiments, the polymer layer 218 may be one of polyimide, benzocyclobutene, or polybenzo-bisoxazole. Thus, as shown in FIG. 2D, the first electrically conducting surface 208a of the wire-bond pad 204 may be located under a first opening in the second passivation layer 212b and the flip-chip bump 206 may extend through a second opening in the second passivation layer 212b.

Similarly, the first electrically conducting surface 208a of the wire-bond pad 204 may be located under a first opening in the polymer layer 218 and the flip-chip bump 206 may extend through a second opening in the polymer layer 218. As such, the first electrically conducting surface 208a of the wire-bond pad 204 may be recessed relative to a top surface 220 of the polymer layer 218, and the second electrically conducting surface 208b of the flip-chip bumps 206 may extend beyond the top surface 220 of the polymer layer 218, as shown in FIG. 2D.

According to various embodiments, the wire-bond pad 204, flip-chip bond pads 210, and the flip-chip bumps 206 may be formed of an electrically conductive material such as copper or aluminum. In other embodiments, other electrically conducting materials such as W, Co, Ru, Mo, Ta, Ti, alloys thereof, may be used. Further, as with the electrical contact structures 216, electrically conducting structures such as the wire-bond pad 204, flip-chip bond pads 210, and the flip-chip bumps 206 may further include a liner layer For example, as shown in FIG. 2D, an under-bump metallurgy layer 222 (i.e., a liner layer) may be formed between the flip-chip bump 206 and the flip-chip bond pad. The under-bump metallurgy layer 222 may include one or more TiN, TaN, WN, TiC, TaC, and WC. Other suitable materials within the contemplated scope of disclosure may also be used to form the under-bump metallurgy layer 222.

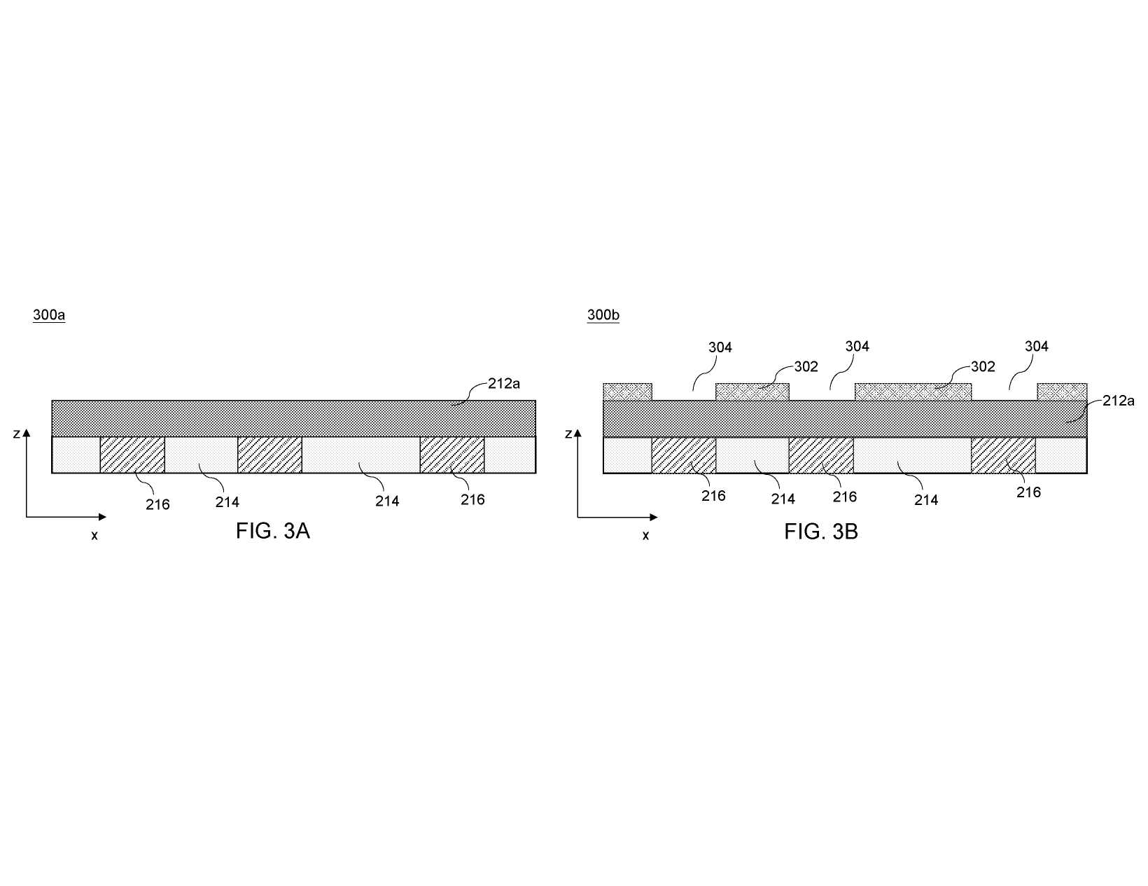

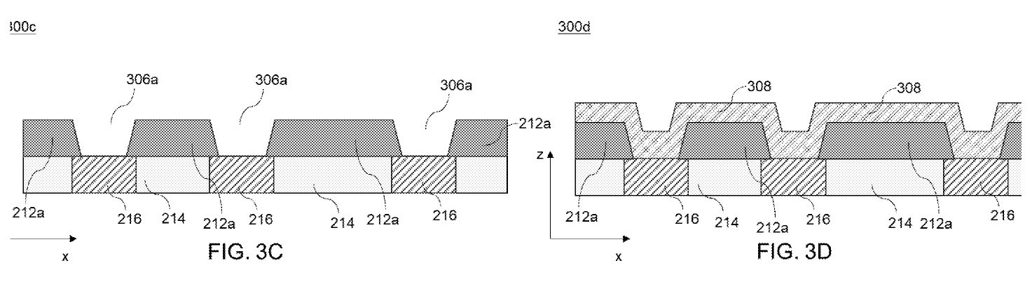

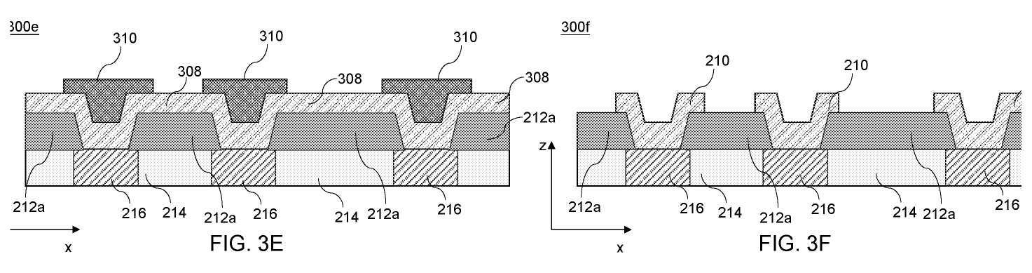

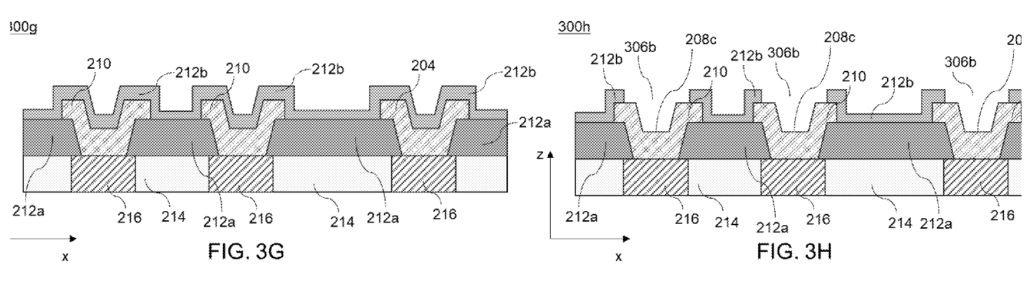

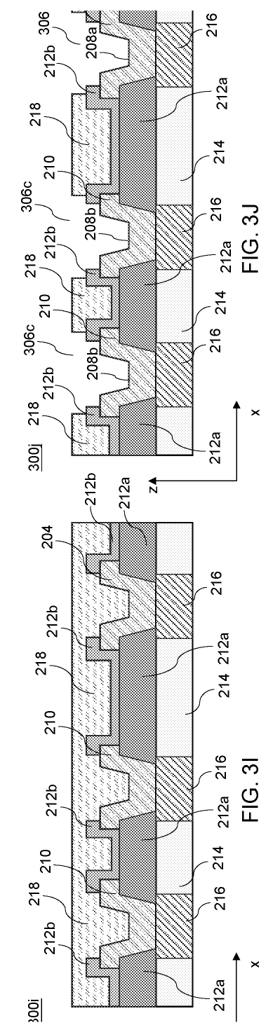

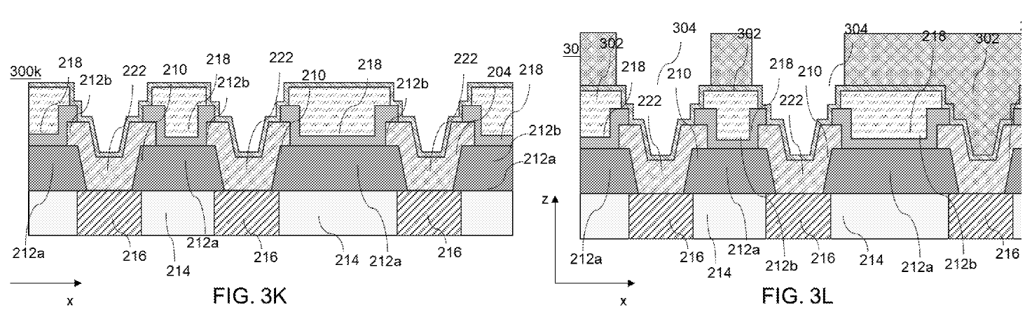

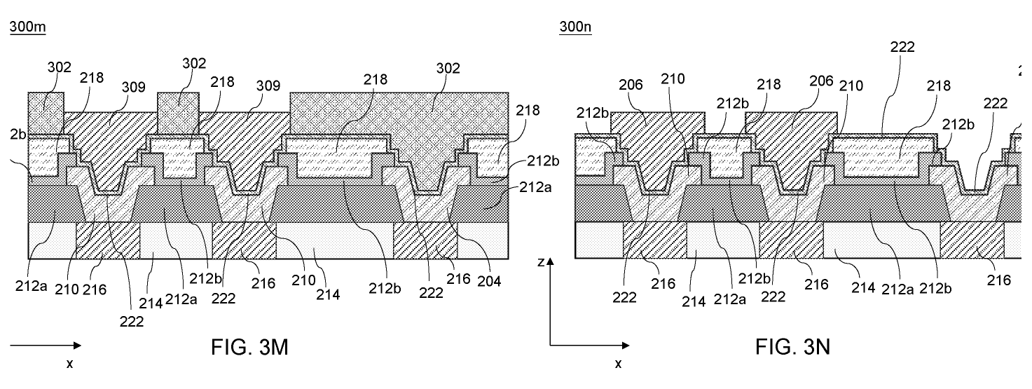

FIG. 3A is a vertical cross-sectional view of an intermediate structure 300a that may be used in the formation of a semiconductor structure (200b, 300c), according to various embodiments. In this regard, the intermediate structure 300a may correspond to the portion 200c (e.g., see FIG. 2C) of a semiconductor structure 200b (e.g., see FIG. 2B) formed on a semiconductor wafer-level structure 200a (e.g., see FIG. 2A). The intermediate structure 300a may be formed by forming a first passivation layer 212a over a dielectric substrate 214 that includes a plurality of electrical contact structures 216 formed therein. As described above, the dielectric substrate 214 and the electrical contact structures 216 may be formed by performing processing operations similar to those described above with reference to FIG. 1. As such, the intermediate structure 300a may include various circuit elements 134 including active and passive components such as transistors, resistors, capacitors, inductors, memory elements, etc.

The first passivation layer 212a may be formed to protect the electrical contact structures 216. The first passivation layer 212a may include a dielectric material such as silicon dioxide, silicon nitride, an organic polymer material, etc. According to various embodiments, the first passivation layer 212a may be deposited using a technique such as chemical vapor deposition (CVD), physical vapor deposition (PVD), or spin-coating, depending on the material being used and the desired properties of the first passivation layer 212a.

FIG. 3B is a vertical cross-sectional view of a further intermediate structure 300b that may be used in the formation of a semiconductor structure (200b, 300c), according to various embodiments. The intermediate structure 300b may be formed from the intermediate structure 300a of FIG. 3A by forming a patterned mask 302 over the first passivation layer 212a. For example, the patterned mask 302 may formed by depositing a blanket layer of a photoresist (not shown) over the first passivation layer 212a. The blanket layer of the photoresist may then be patterned using lithographic techniques to form the patterned mask 302.

In this regard, after exposing the blanket layer of the photoresist to patterned radiation generated by a photomask, a developer may be applied to the exposed photoresist to remove portions of the blanket layer of the photoresist to thereby generate the patterned mask 302. As shown in FIG. 3B, the patterned mask 302 may include openings 304 corresponding to locations of the electrical contact structures 216. As such, the patterned mask 302 may be used during a subsequent etching process to etch the first passivation layer 212a in regions that are not masked by the patterned mask 302, as described in greater detail with reference to FIG. 3C, below.

FIG. 3C is a vertical cross-sectional view of a further intermediate structure 300c that may be used in the formation of a semiconductor structure (200b, 300c), according to various embodiments. The intermediate structure 300c may be formed from the intermediate structure 300b of FIG. 3B by performing an etching process to etch the first passivation layer 212a. The etching process may thereby form openings 306a in the first passivation layer 212a. As shown, the etching process may proceed to remove portions of the first passivation layer 212a such that surfaces of the electrical contact structures 216 may be exposed. The wire-bond pad 204 and flip-chip bond pads 210 may then be formed over the exposed surfaces of the electrical contact structures 216 in subsequent processing operations as described in greater detail with reference to FIGS. 3D to 3F, below.

FIG. 3D is a vertical cross-sectional view of a further intermediate structure 300d that may be used in the formation of a semiconductor structure (200b, 300c), according to various embodiments. The intermediate structure 300d may be formed from the intermediate structure 300c of FIG. 3C by forming a conductive material 308 over the intermediate structure 300c of FIG. 3C. In this regard, the conductive material 308 may be a conductive metal, such as aluminum or copper. Other conductive metal materials are within the contemplated scope of disclosure. The conductive material 308 may be deposited using various techniques such as CVD, PVD, electroplating, etc. The conductive material 308 may then be etched to form the wire-bond pad 204 and flip-chip bond pads 210, as described in greater detail with reference to FIGS. 3E and 3F.

FIG. 3E is a vertical cross-sectional view of a further intermediate structure 300e that may be used in the formation of a semiconductor structure (200b, 300c), according to various embodiments. The intermediate structure 300e may be formed from the intermediate structure 300d of FIG. 3D by forming a hard mask 310 over the conductive material 308. Various materials may be used to form the hard mask 310. For example, the hard mask 310 may include silicon dioxide (SiO₂), silicon nitride (Si₃N₄), a combination of both (e.g., an alternating stack of SiO₂/Si₃N₄ layers), amorphous carbon, amorphous hydrogenated carbon, organo-siloxane based materials, SiN, SiON or combinations thereof.

The hard mask 310 may be formed by depositing a layer of the hard mask material (not shown) over the intermediate structure 300d followed by patterning the hard mask material. The layer of the hard mask material may be deposited using various techniques such as CVD, PVD, etc. A patterned photoresist (not shown) may then be formed over the layer of the hard mask material using lithographic techniques. The patterned photoresist may then be used to etch the hard mask material to thereby form the hard mask 310. As shown in FIG. 3E, the hard mask 310 may include a plurality of disconnected portions that each mask respective portions of the conductive material 308.

FIG. 3F is a vertical cross-sectional view of a further intermediate structure 300f that may be used in the formation of a semiconductor structure (200b, 300c), according to various embodiments. The intermediate structure 300f may be formed from the intermediate structure 300e of FIG. 3E by performing an etching process to remove portions of the conductive material 308 that are not masked by the hard mask 310. In this regard, the wire-bond pad 204 and the flip-chip bond pads 210 may be formed of the remaining portions of the conductive material 308 following the etching process.

After etching the conductive material 308 to form the wire-bond pad 204 and the flip-chip bond pads 210, the hard mask 310 may then be removed by performing a selective etching process. In various embodiments, a wet or dry etching process may be performed. With a wet etching process, for example, hydrofluoric acid (HF) may be used to etch silicon dioxide hard masks 310, and phosphoric acid (H₃PO₄) or hot potassium hydroxide (KOH) solutions may be used to etch Si₃N₄ hard masks 310. With a dry etching process, for example, a plasma containing reactive gases may be used to chemically react with the hard mask 310, causing the hard mask 310 to be removed by sputtering.

FIG. 3G is a vertical cross-sectional view of a further intermediate structure 300g that may be used in the formation of a semiconductor structure (200b, 300c), according to various embodiments. The intermediate structure 300g may be formed from the intermediate structure 300f of FIG. 3F by forming a second passivation layer 212b over the intermediate structure 300f. The second passivation layer 212b may encapsulate and protect the wire-bond pad 204 and the flip-chip bond pads 210. The second passivation layer 212b may include a dielectric material such as silicon dioxide, silicon nitride, an organic polymer material, etc. According to various embodiments, the second passivation layer 212b may be deposited using a technique such as chemical vapor deposition (CVD), physical vapor deposition (PVD), or spin-coating, depending on the material being used and the desired properties of the second passivation layer 212b.

FIG. 3H is a vertical cross-sectional view of a further intermediate structure 300h that may be used in the formation of a semiconductor structure (200b, 300c), according to various embodiments. The intermediate structure 300h may be formed from the intermediate structure 300g of FIG. 3G by performing an etching process to etch the second passivation layer 212b. In this regard, a patterned photoresist (not shown) may be formed over the intermediate structure 300g of FIG. 3G. The patterned photoresist may be used as an etch mask during an etching process that may be performed to generate openings 306b in the second passivation layer 212b. The patterned photoresist may then be removed by ashing or by dissolution with a chemical solvent.

As shown in FIG. 3H, the etching process may proceed to remove portions of the second passivation layer 212b such that surfaces (208a, 208b) of the wire-bond pad 204 and the flip-chip bond pads 210 may be exposed. In this regard, the first electrically conducting surface 208a of the wire-bond pad 204 (described above) may be exposed by the etching process. Further, the etching process may expose an intermediate electrically conducting surface 208c of the flip-chip bond pads 210. As described in greater detail with reference to FIGS. 3I to 3N, the flip-chip bumps 206 may be subsequently formed over the intermediate electrically conducting surface 208c of the flip-chip bond pads 210.

FIG. 3I is a vertical cross-sectional view of a further intermediate structure 300i that may be used in the formation of a semiconductor structure (200b, 300c), according to various embodiments. The intermediate structure 300i may be formed from the intermediate structure 300h of FIG. 3H by forming a polymer layer 218 over the intermediate structure 300h. According to various embodiments, the polymer layer 218 may be one of polyimide, benzocyclobutene, or polybenzo-bisoxazole. Various other materials may be used for the polymer layer 218 in other embodiments. The polymer layer 218 may be deposited, for example, using a spin coating technique. After deposition, the polymer layer 218 may be lithographically pattered to form openings 306c in the polymer layer 218 as described in further detail with reference to FIG. 3J, below.

FIG. 3J is a vertical cross-sectional view of a further intermediate structure 300j that may be used in the formation of a semiconductor structure (200b, 300c), according to various embodiments. The intermediate structure 300j may be formed from the intermediate structure 300i of FIG. 3I by lithographically patterning the polymer layer 218. In this regard, the polymer layer 218 may be chosen to be photoresist polymer such as polyimide. As such, the polymer layer 218 may be patterned through exposure to ultra-violet (UV) radiation. The UV radiation may be patterned by passing the UV radiation through a photomask to impart a desired spatial pattern to the UV radiation. The polymer layer 218 may then be developed and the openings 306c may be formed by selective removal of portions of the polymer layer 218. The patterned polymer layer 218 may then be cured by subjecting the patterned polymer layer 218 to one or more elevated temperatures to cure and anneal the polymer layer 218. For example, when polyimide is used, the polymer layer 218 may be subjected to a prebake process, an imidization process, a post-cure process, and an annealing process.

The prebake process may be conducted at a relatively low temperature (e.g., 100-150°C) for a short time (e.g., 15-30 minutes) to remove some of a solvent and moisture. The imidization process may be performed as the primary curing process and may be conducted at higher temperatures (e.g., 250-350°C) for an extended period (e.g., 1-2 hours or more). During this stage, polyamic acid may undergo imidization, forming the polyimide structure. The post-cure process may be performed at a slightly higher temperature (e.g., 350-400°C) for a shorter time to enhance the film's properties and remove any remaining volatiles.

Annealing is a heat treatment process that may follow curing and may be used to optimize the properties of the polyimide film. The specific annealing temperature and time depend on the desired properties, such as mechanical stability, stress relief, and electrical characteristics. Annealing temperatures for polyimide films typically range from 250°C to 400°C. The duration of annealing can vary from 30 minutes to several hours, depending on the material and desired results. Longer annealing times may be used for stress relief and improved mechanical properties. The annealing process may involve multiple steps, with the temperature gradually ramping up and down to minimize thermal stress and promote uniform properties across the film.

In an alternative embodiment, the polymer layer 218 may be deposited, as shown in FIG. 3I, and may be cured prior to formation of the openings 306c of FIG. 3J. In this regard, the polymer layer 218 may be cured and then etched to thereby form the openings 306c. In this regard, a patterned photoresist (not shown) may be formed over the cured polymer layer 218. The polymer layer 218 may then etched to form openings 306c in the polymer layer 218. The etch process may be carried out until a sufficient amount of the polymer layer 218 is removed so that surfaces (208a, 208b) of the wire-bond pad 204 and the flip-chip bond pads 210 may be exposed.

Various etching processes may be used to etch the polymer layer 218. For example, when polyimide is used as the polymer layer 218, a dry etch or a wet etch process may be performed. An example dry etch process may include plasma etching in which a plasma containing reactive gases (e.g., oxygen, fluorine, or CF₄) may be used to chemically react with and remove the polyimide material. The specific gas and conditions are chosen based on the polyimide formulation. Wet etching may involve introducing a chemical solution that selectively dissolves the polyimide. Common wet etchants for polyimide include N-methyl-2-pyrrolidone (NMP) or various formulations of organic solvents.

FIG. 3K is a vertical cross-sectional view of a further intermediate structure 300k that may be used in the formation of a semiconductor structure (200b, 300c), according to various embodiments. The intermediate structure 300k may be formed from the intermediate structure 300j of FIG. 3K by forming an under-bump metallurgy layer 222 (i.e., a liner layer) over the intermediate structure 300j. The under-bump metallurgy layer 222 may include one or more TiN, TaN, WN, TiC, TaC, and WC and may be deposited using PVD or other processes. Other suitable materials within the contemplated scope of disclosure may also be used.

FIG. 3L is a vertical cross-sectional view of a further intermediate structure 300l that may be used in the formation of a semiconductor structure (200b, 300c), according to various embodiments. The intermediate structure 300l may be formed from the intermediate structure 300k of FIG. 3L by forming a patterned photoresist 302 over the intermediate structure 300k. The patterned mask 302 may formed by depositing a blanket layer of a photoresist (not shown) over the intermediate structure 300k. The blanket layer of the photoresist may then be patterned using lithographic techniques to form the patterned mask 302. In this regard, after exposing the blanket layer of the photoresist to patterned radiation generated by a photomask, a developer may be applied to the exposed photoresist to remove portions of the blanket layer of the photoresist to thereby generate the patterned mask 302. As shown in FIG. 3L, the patterned mask 302 may include openings 304 corresponding to locations of the flip-chip bond pads 210. The patterned photoresist 302 may then be used to form the flip-chip bumps 206 in further processing operations as described in greater detail with reference to FIGS. 3M and 3N, below.

FIGS. 3M and 3N are vertical cross-sectional views of a further intermediate structures (300m, 300n) that may be used in the formation of a semiconductor structure (200b, 300c), according to various embodiments. The intermediate structure 300m may be formed from the intermediate structure 300l of FIG. 3M by deposition of a conducting material 309 in regions that are not masked by patterned photoresist 302 to thereby the flip-chip bumps 206, as shown in FIG. 3N. Conductive materials 309 that may be used to form the flip-chip bumps 206 may include copper, tungsten, or other conductive metals. Such materials may be deposed, for example, by electroplating, electroless plating, etc. In an example embodiment, an electroplating process may be used for plating the conductive material 309 over the exposed conductive areas of the under-bump metallurgy layer 222 within openings 304 of the patterned photoresist 302.

Once the flip-chip bumps 206 have been formed over the under-bump metallurgy layer 222 using the patterned photoresist 302 as a template, the patterned photoresist 302 may then be removed using a suitable removal process. The resulting intermediate structure 300n is shown in FIG. 3N. In this regard, a plasma ashing process may be used to remove the patterned photoresist 302, whereby the temperature of the patterned photoresist 302 may be increased until the patterned photoresist 302 experiences a thermal decomposition that allows the patterned photoresist 302 to be removed. In other embodiments, other suitable processes, such as a wet strip, may be utilized. Removal of the patterned photoresist 302 may expose the underlying portions of the under-bump metallurgy layer 222, as shown in FIG. 3N. Exposed portions of the under-bump metallurgy layer 222 (e.g., portions remaining over the polymer layer 218) may then be removed by an etching process to form the semiconductor structure (200b, 200c) shown in FIGS. 2B to 2D.

In this regard, portions of the under-bump metallurgy layer 222 may be removed, for example, in a dry etching process in which reactants may be directed towards the under-bump metallurgy layer 222, using the flip-chip bumps 206 as masks. Alternatively, etchants may be sprayed or otherwise put into contact with the under-bump metallurgy layer 222 to remove the exposed portions of the under-bump metallurgy layer 222. After the exposed portion of the under-bump metallurgy layer 222 has been removed (e.g., etched away), the resulting semiconductor structure (200b, 200c) is shown in FIG. 2D.

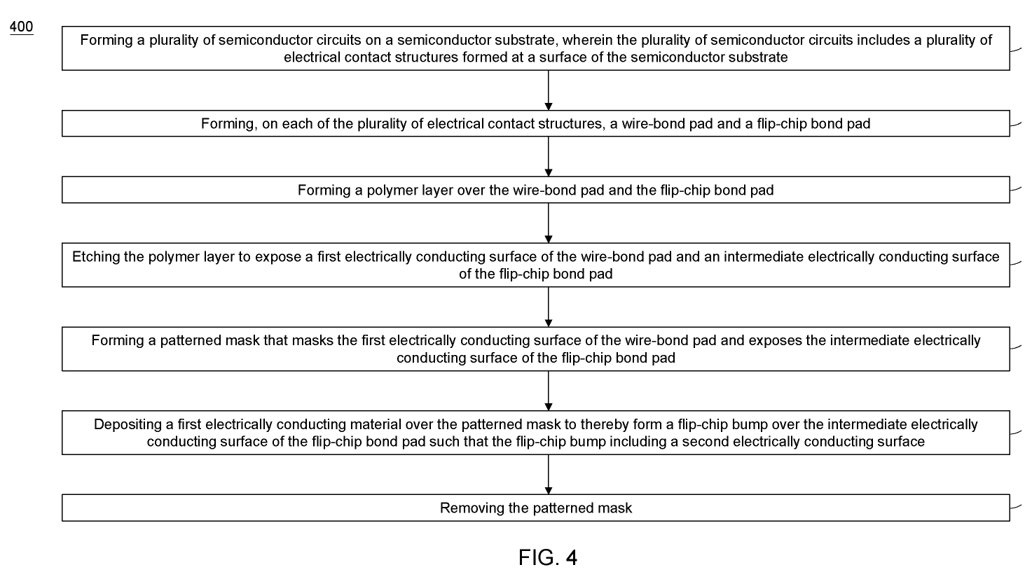

FIG. 4 is a flowchart illustrating operation of a method 400 of forming a semiconductor structure (200a, 200b, 200c), according to various embodiments. In operation 402, the method 400 may include forming a plurality of semiconductor circuits 134 on a semiconductor substrate 102. The plurality of semiconductor circuits 134 may be formed to include a plurality of electrical contact structures 216 formed at a surface of a dielectric substrate 214. In operation 404, the method 400 may include forming, on each of the plurality of electrical contact structures 216, a wire-bond pad 204 and a flip-chip bond pad 210. In operation 406, the method 400 may include forming a polymer layer 218 over the wire-bond pad 204 and the flip-chip bond pad 210. In operation 408, the method 400 may include etching the polymer layer 218 to expose a first electrically conducting surface 208a of the wire-bond pad 204 and an intermediate electrically conducting surface 208c of the flip-chip bond pad 210.

In operation 410, the method 400 may include forming a patterned mask 302 that masks the first electrically conducting surface 208a of the wire-bond pad 204 and exposes the intermediate electrically conducting surface 208c of the flip-chip bond pad 210. In operation 412, the method 400 may include depositing a first electrically conducting material 309 over the patterned mask 302 to thereby form a flip-chip bump 206 over the intermediate electrically conducting surface 208c of the flip-chip bond pad 210 such that the flip-chip bump 206 includes a second electrically conducting surface 208b. In operation 414, the method 400 may include removing the patterned mask 302.

The method 400 may further include forming a first passivation layer 212a over the plurality of electrical contact structures 216 and etching the first passivation layer 212a to expose a first one of the plurality of electrical contact structures 216 and a second one of the plurality of electrical contact structures 216. The method 400 may further include depositing a second electrically conducting material 308 over the first passivation layer 212a, the first one of the plurality of electrical contact structures 216, and the second one of the plurality of electrical contact structures 216. The method 400 may further include etching the second electrically conducting material 308 to form the wire-bond pad 204 and the flip-chip bond pad 210.

According to various embodiments, the method 400 may further include forming a second passivation layer 212b over the wire-bond pad 204 and the flip-chip bond pad 210 and etching the second passivation layer 212b to expose the first electrically conducting surface 208a of the wire-bond pad 204 and the intermediate electrically conducting surface 208c of the flip-chip bond pad 210. In forming the polymer layer 218 according to operation 406, the method 400 may further include forming the polymer layer 218 over the second passivation layer 212b. The method 400 may further include forming an under-bump metallurgy layer 222 over the flip-chip bond pad 210 prior to depositing the first electrically conducting material 309 such that the under-bump metallurgy layer 222 is formed between the flip-chip bump 206 and the flip-chip bond pad 210. The method may further include forming the first electrically conducting surface 208a of the wire-bond pad 204 to be recessed relative to a surface 220 of the polymer layer 218. The method may further include forming the second electrically conducting surface 208b of the flip-chip bump 206 to extend beyond the surface 220 of the polymer layer 218.

Referring to all drawings and according to various embodiments of the present disclosure, a semiconductor structure (200b, 200c) is provided. The semiconductor structure (200b, 200c) may include a wire-bond pad 204 including a first electrically conducting surface 208a and a flip-chip bump 206 including a second electrically conducting surface 208b. The semiconductor structure (200b, 200c) may further include a polymer layer 218 formed over a surface of the semiconductor structure (200b, 200c) such that the first electrically conducting surface 208a of the wire-bond pad 204 is located under a first opening 306c in the polymer layer 218, and the flip-chip bump 206 also extends through a second opening 306c in the polymer layer 218. The semiconductor structure (200b, 200c) may further include a flip-chip bond pad 210 and a first passivation layer 212a formed over a surface of the semiconductor structure (200b, 200c) that includes a plurality of electrical contact structures 216.

According to various embodiments, the wire-bond pad 204 may extend through the first passivation layer 212a and may be electrically connected to a first one of a plurality of electrical contact structures 216. Similarly, the flip-chip bump 206 may be connected to the flip-chip bond pad 210, which may extend through the first passivation layer 212a and may be electrically connected to a second one of the plurality of electrical contact structures 216. The semiconductor structure (200b, 200c) may further include an under-bump metallurgy layer 222 formed between the flip-chip bump 206 and the flip-chip bond pad 210. The semiconductor structure (200b, 200c) may further include a second passivation layer 212b formed over the first passivation layer 212a such that the first electrically conducting surface 208a of the wire-bond pad 204 is located under a third opening 306b in the second passivation layer 212b. Similarly, the flip-chip bump 206 may extend through a fourth opening 306b in the second passivation layer 212b. According to various embodiments, the polymer layer 218 may be formed over the second passivation layer 212b

According to various embodiments, the polymer layer 218 may include one of polyimide, benzocyclobutene, or polybenzo-bisoxazole. Further, each of the wire-bond pad 204 and the flip-chip bond pad 210 include copper or aluminum. In further embodiments, the under-bump metallurgy layer 222 may include titanium and copper and the flip-chip bump 206 may include copper. According to various embodiments, the first electrically conducting surface 208a of the wire-bond pad 204 may be recessed relative to a surface 220 of the polymer layer 218 and the second electrically conducting surface 208b of the flip-chip bump 206 may extend beyond the surface 220 of the polymer layer 218.

According to another aspect of the present disclosure, a wafer-level semiconductor structure (200a, 200b, 200c) is provided. The wafer-level semiconductor structure (200a, 200b, 200c) may include a semiconductor substrate 102 including a plurality of semiconductor structures (200b, 200c) and a plurality of bonding structures (204, 206) electrically connected to the plurality of semiconductor structures (200b, 200c) and formed on a dielectric substrate 214. Each of the plurality of bonding structures (204, 206) may include a wire-bond pad 204 including a first electrically conducting surface 208a and a flip-chip bump 206 including a second electrically conducting surface 208b.

The wafer-level semiconductor structure (200a, 200b, 200c) may further include a first passivation layer 212a; a second passivation layer 212b; and a polymer layer 218 formed over the second passivation layer 212b, wherein the first electrically conducting surface 208a of the wire-bond pad 204 is located under first openings 306a in the first passivation layer 212a, second openings 306b in the second passivation layer 212b, and third openings 306c in the polymer layer 218, and wherein the flip-chip bump 206 extends through the first openings 306a in the first passivation layer 212a, second openings 306b in the second passivation layer 212b, and third openings 306c in the polymer layer 218.

In one embodiment, the polymer layer 218 may include one of polyimide, benzocyclobutene, or polybenzo-bisoxazole. In one embodiment, the wafer-level semiconductor structure (200a, 200b, 200c) may further include: a flip-chip bond pad 210; and an under-bump metallurgy layer 222 formed over the flip-chip bond pad 210, wherein the flip-chip bump 206 is formed over the under-bump metallurgy layer 222. In one embodiment, the first electrically conducting surface 208a of the wire-bond pad 204 may be recessed relative to a top surface 220 of the polymer layer 218; and the second electrically conducting surface 208b of the flip-chip bump 206 may extend beyond the top surface 220 of the polymer layer 218.

Disclosed embodiments may be advantageous by providing wafer-level semiconductor structures (200a, 200b, 200c) having wire-bond pads 204 and flip-chip bumps 206 that have electrically conductive surfaces (208a, 208b). In this regard, a polymer layer 218 deposited over the wire-bond pads 204 during formation of the flip-chip bumps 206 may be etched following the formation of the flip-chip bumps 206 to thereby expose the conductive surface 208a of the wire-bond pads 204. As such, wafer-level testing may be carried out on both wire-bond pads 204 and flip-chip bumps 206 before singulating wafer-level semiconductor structures 200a into semiconductor dies. Such testing may provide advantages by allowing screening for potential damage that may result due to multiple CMOS fabrication processes and high temperatures used in the formation of the polymer layer 218. Package-level testing may then be carried out once the semiconductor dies have been singulated and assembled into semiconductor packages. Semiconductor dies having both wire-bond pads 204 and flip-chip bumps 206 may be used in situations where both flip-chip and wire bonding may be used within the same semiconductor package and may provide flexibility in how such dies are integrated into different packaging configurations.

The foregoing outlines features of several embodiments so that those skilled in the art may better understand the aspects of this disclosure. Those skilled in the art should appreciate that they may readily use this disclosure as a basis for designing or modifying other processes and structures for carrying out the same purposes and/or achieving the same advantages of the embodiments introduced herein. Those skilled in the art should also realize that such equivalent constructions do not depart from the spirit and scope of this disclosure, and that they may make various changes, substitutions, and alterations herein without departing from the spirit and scope of this disclosure.

What is claimed is:

1. A semiconductor structure, comprising:
a wire-bond pad comprising a first electrically conducting surface;
a flip-chip bump comprising a second electrically conducting surface; and
a polymer layer formed over a surface of the semiconductor structure;
wherein the first electrically conducting surface of the wire-bond pad is located under a first opening in the polymer layer, and
wherein the flip-chip bump extends through a second opening in the polymer layer.

2. The semiconductor structure of claim 1, further comprising:
a flip-chip bond pad; and
a first passivation layer formed over the surface of the semiconductor structure, wherein the surface of the semiconductor structure comprises a plurality of electrical contact structures, wherein:
the wire-bond pad extends through the first passivation layer and is electrically connected to a first one of the plurality of electrical contact structures; and
the flip-chip bump is connected to the flip-chip bond pad, wherein the flip-chip bond pad extends through the first passivation layer and is electrically connected to a second one of the plurality of electrical contact structures.

3. The semiconductor structure of claim 2, further comprising an under-bump metallurgy layer formed between the flip-chip bump and the flip-chip bond pad.

4. The semiconductor structure of claim 2, further comprising a second passivation layer formed over the first passivation layer,
wherein the first electrically conducting surface of the wire-bond pad is located under a third opening in the second passivation layer, and
wherein the flip-chip bump extends through a fourth opening in the second passivation layer.

5. The semiconductor structure of claim 4, wherein the polymer layer is formed over the second passivation layer.

6. The semiconductor structure of claim 5, wherein the polymer layer comprises one of polyimide, benzocyclobutene, or polybenzo-bisoxazole.

7. The semiconductor structure of claim 2, wherein each of the wire-bond pad and the flip-chip bond pad comprise copper or aluminum.

8. The semiconductor structure of claim 3, wherein the under-bump metallurgy layer further comprises titanium and copper.

9. The semiconductor structure of claim 1, wherein the flip-chip bump comprises copper.

10. The semiconductor structure of claim 5, wherein:
the first electrically conducting surface of the wire-bond pad is recessed relative to a surface of the polymer layer; and
the second electrically conducting surface of the flip-chip bump extends beyond the surface of the polymer layer.

11. A wafer-level semiconductor structure, comprising:
a semiconductor substrate comprising a plurality of semiconductor structures; and
a plurality of bonding structures electrically connected to each of the plurality of semiconductor structures and formed on a dielectric substrate, wherein each of the plurality of bonding structures comprises:
a wire-bond pad comprising a first electrically conducting surface; and
a flip-chip bump comprising a second electrically conducting surface;
a first passivation layer;
a second passivation layer; and
a polymer layer formed over the second passivation layer,
wherein the first electrically conducting surface of the wire-bond pad is located under first openings in the first passivation layer, second openings in the second passivation layer, and third openings in the polymer layer, and
wherein the flip-chip bump extends through the first openings in the first passivation layer, the second openings in the second passivation layer, and the third openings in the polymer layer.

12. The wafer-level semiconductor structure of claim 11, wherein the polymer layer comprises one of polyimide, benzocyclobutene, or polybenzo-bisoxazole.

13. The wafer-level semiconductor structure of claim 12, further comprising:
a flip-chip bond pad; and
an under-bump metallurgy layer formed over the flip-chip bond pad,
wherein the flip-chip bump is formed over the under-bump metallurgy layer.

14. The wafer-level semiconductor structure of claim 12, wherein:
the first electrically conducting surface of the wire-bond pad is recessed relative to a surface of the polymer layer; and
the second electrically conducting surface of the flip-chip bump extends beyond the surface of the polymer layer.

15. A semiconductor structure, comprising:
a dielectric substrate comprising a plurality of electrical contact structures formed therein;
a first passivation layer formed over the dielectric substrate;
a wire-bond pad extending through the first passivation layer and electrically connected to a first one of the plurality of electrical contact structures, wherein the wire-bond pad comprises a first electrically conducting surface;
a flip-chip bump electrically connected to a second one of the plurality of electrical contact structures, wherein the flip-chip bump comprises a second electrically conducting surface; and
a polymer layer formed over the first passivation layer,
wherein the first electrically conducting surface of the wire-bond pad is located under a first opening in the polymer layer, and
wherein the flip-chip bump extends through a second opening in the polymer layer.

16. The semiconductor structure of claim 15, further comprising a flip-chip bond pad extending through the first passivation layer and electrically connected to the second one of the plurality of electrical contact structures, wherein the flip-chip bump is formed over the flip-chip bond pad.

17. The semiconductor structure of claim 16, further comprising a second passivation layer formed over the first passivation layer,
wherein the first electrically conducting surface of the wire-bond pad is located under a third opening in the second passivation layer, and
wherein the flip-chip bump extends through a fourth opening in the second passivation layer.

18. The semiconductor structure of claim 17, wherein the polymer layer is formed over the second passivation layer.

19. The semiconductor structure of claim 16, further comprising an under-bump metallurgy layer formed between the flip-chip bump and the flip-chip bond pad.

20. The semiconductor structure of claim 15, wherein the first electrically conducting surface of the wire-bond pad is recessed relative to a top surface of the polymer layer, and wherein the second electrically conducting surface of the flip-chip bump extends beyond the top surface of the polymer layer.
